(19) United States
(12) Patent Application Publication
(10) Pub. No.: US 2008/0254389 A1
(43) Pub. Date: Oct. 16, 2008

(54) Method of Making Lithographic Printing Plates

(75) Inventors: Joan Vermeersch, Deinze (BE); Huub Van Aert, Pulderbos (BE)

Correspondence Address: AGFA;c/o KEATING & BENNETT, LLP, 1800 Alexander Bell Drive, SUITE 200, Reston, VA, 20191, US

(73) Assignee: AGFA GRAPHICS NV, Mortsel (BE)

(21) Appl. No.: 11/576,394

(22) PCT Filed: Sep. 15, 2005
(86) PCT No.: PCT/EP05/54585

§ 371 Date: Jul. 25, 2007

Related U.S. Application Data
(60) Provisional application No. 60/617,694, filed on Oct. 12, 2004.

(30) Foreign Application Priority Data
Oct. 1, 2004 (EP) 04104827.3

(51) Int. Cl. G03F 7/20

(52) U.S. Cl. 430/302

(57) ABSTRACT

A method for preparing a lithographic printing plate includes the steps of—providing a lithographic printing plate precursor including: a support having a hydrophilic surface or which is provided with a hydrophilic layer; and a coating provided on the support and including an image recording layer including hydrophobic thermoplastic polymer particles having an average particle size between about 40 nm and about 63 nm and a hydrophilic binder, the coating further including a pigment present in the image recording layer or in an additional layer of the coating, —image-wise exposing the coating, thereby inducing coalescence of the thermoplastic polymer particles at the exposed areas of the image recording layer; —developing the precursor by applying a gum solution to the coating, thereby removing the non-exposed areas of the image recording layer from the support; and—optionally, baking the developed precursor; wherein the hydrophobic thermoplastic polymer particles have an average particle size between about 40 nm and about 63 nm; the amount of the hydrophobic thermoplastic polymer particles is more than about 70% and less than about 85% by weight, relative to the image recording layers; and the pigment has a hydrophilic surface and provides a visible image after the image-wise exposing and developing with the gum solution. The lithographic printing plate precursor has an improved sensitivity, and the obtained lithographic printing plate exhibits an excellent clean-out, no toning, and a high printing run length.

### BACKGROUND OF THE INVENTION

1. Field of the Invention

The present invention relates to a method for making a lithographic printing plate whereby a printing plate precursor, having an improved sensitivity, is image-wise exposed and developed with a gum solution.

2. Description of the Related Art

In lithographic printing, a so-called printing master such as a printing plate is mounted on a cylinder of the printing press. The master carries a lithographic image on its surface and a printed copy is obtained by applying ink to the image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called “driographic” printing, the lithographic image consists of ink-accepting and ink-adhesive (ink-repelling) areas and during driographic printing, only ink is supplied to the master.

Printing masters are generally obtained by the so-called computer-to-film (CtF) method wherein various pre-press steps such as typeface selection, scanning, color separation, screening, trapping, layout, and imposition are accomplished digitally and each color selection is transferred to graphic arts film using an image-setter. After processing, the film can be used as a mask for the exposure of an imaging material called a plate precursor and after plate processing, a printing plate is obtained which can be used as a master. Since about 1995, the so-called ‘computer-to-plate’ (CtP) method has gained a lot of interest. This method, also called ‘direct-to-plate’, bypasses the creation of film because the digital document is transferred directly to a plate precursor by a so-called plate-setter.

Especially thermal plates, which are sensitive to heat or infrared light, are widely used in computer-to-plate methods because of their daylight stability. Such thermal materials may be exposed directly to heat, e.g., by a thermal head, but preferably include a compound that converts absorbed light into heat and are therefore suitable for exposure by lasers, especially infrared laser diodes. The heat, which is generated on image-wise exposure, triggers a (physico-)chemical process, such as ablation, polymerization, insolubilization by cross-linking of a polymer, decomposition, or particle coagulation of a thermoplastic polymer latex, and after optional processing, a lithographic image is obtained. Many thermal plate materials are based on heat-induced ablation. A problem associated with ablative plates is the generation of debris which is difficult to remove and may disturb the printing process or may contaminate the exposure optics of the plate-setter. As a result, such ablative plates require a processing step for removing the debris from the exposed material.

EP 1 075 941 discloses a radiation-sensitive printing plate precursor wherein a photo-heat conversion agent is incorporated and wherein the photo-heat conversion agent is a particulate metal oxide including an organic photo-heat conversion compound encapsulated therein.

U.S. Pat. No. 4,841,040 discloses a novel phosphated, oxidized starch having a molecular weight of about 1,500 to about 40,000 Daltons, a carboxyl degree of substitution of 0.30 to 0.96, and a phosphate degree of substitution of from about 0.002 to about 0.005, which is useful as a replacement for gum arabic in gumming and fountain solutions for lithography.

U.S. Pat. No. 4,245,031 discloses photopolymerizable compositions containing a polymer having a plurality of salt-forming groups, two specific ethylenically unsaturated compounds and a radiation-sensitive, free-radical generating system. The compositions provide photopolymerizable elements which have outstanding photospeeds and are relatively insensitive to oxygen.

EP 770 497 discloses a method wherein an imaging material including an image-recording layer of a hydrophilic binder, a compound capable of converting light to heat and hydrophobic thermoplastic polymer particles, is image-wise exposed, thereby inducing coalescence of the polymer particles and converting the image-recording layer into an hydrophobic phase which defines the printing areas of the printing master. Subsequently the image-wise exposed precursor is developed by rinsing it with plain water or an aqueous liquid.

EP 514 145 discloses a radiation-sensitive plate which includes a coating including core-shell particles having a water insoluble heat softenable core component and a shell component which is soluble or swellable in aqueous alkaline medium. The radiation causes selected particles to coalescence, at least partially, to form an image and the non-coalesced particles are then selectively removed by an aqueous alkaline developer.

In EP 1 614 538 A, EP 1 614 539 A, and EP 1 614 540 A, a lithographic printing plate precursor is disclosed which includes on a hydrophilic support a coating including an image-recording layer which includes hydrophobic thermoplastic polymer particles having an average particle size ranging from 45 nm to 63 nm and wherein the amount of thermoplastic polymer particles is at least 70% by weight relative to the image-recording layer. After exposure, the precursors are developed with an alkaline developing solution whereby the non-image areas of the coating are removed.

EP 1 342 568 discloses a method wherein an imaging material including an image-recording layer of a hydrophilic binder, a compound capable of converting light to heat and hydrophobic thermoplastic polymer particles, is image-wise exposed, thereby inducing coalescence of the polymer particles and converting the image-recording layer into an hydrophobic phase which defines the printing areas of the printing master. Subsequently, the image-wise exposed precursor is processed with a gum solution, thereby developing and gumming the plate in a single step.

In this single step process, the image-recording layer at the non-exposed areas is removed with the gum solution from the support, revealing the hydrophilic surface of the support, also called “clean-out”, and simultaneously the hydrophilic surface in these non-image areas is protected from contamination (fingerprints, fats, oils, dust, oxidation, etc.) by the gum.

A plate system, AZURA (trademark from AGFA), that works according to the above-described mechanism, has been introduced to the market in May 2004. A problem associated with this printing plate precursor is the low sensitivity, i.e., the plate precursor needs a higher energy dose on image-wise exposure to obtain a sufficient coalescence of the polymer particles such that the non-exposed areas can be removed by the gum solution without affecting the exposed areas. This implies that the plate requires a longer exposure time and/or a higher power laser, resulting in a lower speed. If a printing plate precursor is exposed with an energy dose which is too low in relation with its sensitivity, a lower quality for the lithographic printing properties may be obtained. This lower quality may result in a lower resolution, i.e., the precursor with the reduced sensitivity is not capable of rendering fine dots of a high resolution screen after exposure with the lower energy dose and after developing with a gum solution. Also, the run length of the plate may be reduced as a result of a too low energy dose in relation with the sensitivity of the precursor due to an insufficient coalescence of the polymer particles in the exposed areas. It is further important for a high quality printing plate that the hydrophobic-hydrophilic differentiation in the coating is sufficient such that an excellent clean-out can be obtained, i.e., the non-exposed areas are completely removed from the support revealing the hydrophilic surface without affecting the exposed areas. An insufficient clean-out may further result in toning on the press, i.e., an undesirable increased tendency of ink-acceptance in the non-image areas.

### SUMMARY OF THE INVENTION

In order to overcome the problems described above, preferred embodiments of the present invention provide a method for making a lithographic printing plate wherein the lithographic printing plate precursor has an improved sensitivity and wherein the plate exhibits an excellent clean-out, no toning, and a high printing run length.

According to preferred embodiments of the present invention, a method of preparing a lithographic printing plate includes the steps of providing a lithographic printing plate precursor including a support having a hydrophilic surface or which is provided with a hydrophilic layer; a coating provided on the support and including an image recording layer including hydrophobic thermoplastic polymer particles and a hydrophilic binder, the coating further including a pigment that is present in the image recording layer or in an additional layer of the coating; image-wise exposing the coating, thereby inducing coalescence of the thermoplastic polymer particles at the exposed areas of the image recording layer; developing the precursor by applying a gum solution to the coating, thereby removing the non-exposed areas of the image recording layer from the support; and optionally, baking the developed precursor; wherein the hydrophobic thermoplastic polymer particles have an average particle size between about 40 nm and about 63 nm; the amount of the hydrophobic thermoplastic polymer particles in the image recording layer is more than about 70% and less than about 85% by weight, relative to the image recording layer; and the pigment has a hydrophilic surface and provides a visible image after the image-wise exposing and developing with the gum solution.

Other specific features of various preferred embodiments of the present invention are described below and are further defined in the claims. Further features, elements, steps, characteristics, and advantages of various preferred embodiments of the present invention will become apparent from the following description.

### DETAILED DESCRIPTION OF PREFERRED EMBODIMENTS

In the present description, all concentrations of compounds are expressed as percentage by weight, hereinafter also referred to as “wt. %” or “% wt”, unless otherwise indicated.

The lithographic printing plate precursor used in a preferred method of the present invention is preferably negative-working and develops a lithographic image consisting of hydrophobic and hydrophilic areas at the exposed and non-exposed areas respectively. The hydrophobic areas and the hydrophilic areas are respectively defined by the coating and by the support, which has a hydrophilic surface or is provided with a hydrophilic layer.

The support may be a sheet-like material such as a plate or it may be a cylindrical element such as a sleeve which can be slid around a print cylinder of a printing press. Preferably, the support is preferably a metal support such as aluminum or stainless steel.

A particularly preferred lithographic support is a grained and anodized aluminum support. Graining and anodizing of aluminum supports is well known. The grained aluminum support used in the material of preferred embodiments of the present invention is preferably an electrochemically grained support. The acid used for graining can be, e.g., nitric acid or sulfuric acid. The acid used for graining preferably includes hydrogen chloride. Also mixtures of, e.g., hydrogen chloride and acetic acid can be used. The relation between electrochemical graining and anodizing parameters such as electrode voltage, nature, and concentration of the acid electrolyte or power consumption on the one hand and the obtained lithographic quality in terms of Ra and anodic weight (g/m² of Al₂O₃ formed on the aluminum surface) on the other hand is well known. More details about the relation between various production parameters and Ra or anodic weight can be found in, e.g., the article “Management of Change in the Aluminium Printing Industry” by F. R. Mayers, published in the ATB Metallurgie Journal, Volume 42 No. 1-2 (2002) pp. 69-77.

The anodized aluminum support may be subjected to a so-called post-anodic treatment to improve the hydrophilic properties of its surface. For example, the aluminum support may be silicated by treating its surface with a sodium silicate solution at an elevated temperature, e.g., 95° C. Alternatively, a phosphate treatment may be applied which involves treating the aluminum oxide surface with a phosphate solution that may further contain an inorganic fluoride. Further, the aluminum oxide surface may be rinsed with a citric acid or citrate solution. This treatment may be carried out at room temperature or may be carried out at a slightly elevated temperature of about 30° C. to about 50° C. A further interesting treatment involves rinsing the aluminum oxide surface with a bicarbonate solution. Still further, the aluminum oxide surface may be treated with polyvinylphosphonic acid, polyvinylmethylphosphonic acid, phosphoric acid esters of polyvinyl alcohol, polyvinylsulfonic acid, polyvinylbenzenesulfonic acid, sulfuric acid esters of polyvinyl alcohol, and acetals of polyvinyl alcohols formed by reaction with a sulfonated aliphatic aldehyde.

Another useful post-anodic treatment may be carried out with a solution of polyacrylic acid or a polymer including at least 30 mol % of acrylic acid monomeric units, e.g., GLASCOL D15, a polyacrylic acid, commercially available from ALLIED COLLOIDS.

The support can also be a flexible support, which may be provided with a hydrophilic layer, hereinafter called ‘base layer’. The flexible support is, e.g., paper, plastic film, or aluminum. Preferred examples of plastic film are polyethylene terephthalate film, polyethylene naphthalate film, cellulose acetate film, polystyrene film, polycarbonate film, etc. The plastic film support may be opaque or transparent.

The base layer is preferably a cross-linked hydrophilic layer obtained from a hydrophilic binder cross-linked with a hardening agent such as formaldehyde, glyoxal, polyisocyanate, or a hydrolyzed tetra-alkylorthosilicate. The latter is particularly preferred. The thickness of the hydrophilic base layer may vary in the range of 0.2 μm to 25 μm and is preferably 1 μm to 10 μm. More details of preferred embodiments of the base layer can be found in, e.g., EP-A 1 025 992.

The coating provided on the support includes an image-recording layer which contains hydrophobic thermoplastic polymer particles.

In accordance with preferred embodiments of the present invention, the hydrophobic polymer particles have a number average particle size between about 40 nm and about 63 nm, preferably between about 45 nm and about 63 nm, more preferably between about 45 nm and about 59 nm. Herein, the particle size is defined as the particle diameter, measured by Photon Correlation Spectrometry, also known as Quasi-Elastic or Dynamic Light-Scattering. This technique is a convenient method for measuring the particle size and the values of the measured particle size match well with the particle size measured with transmission electronic microscopy (TEM) as disclosed by Stanley D. Duke et al. in Calibration of Spherical Particles by Light Scattering, in Technical Note-002B, May 15, 2000 (revised Jan. 3, 2000 from a paper published in Particulate Science and Technology 7, pp. 223-228 (1989). As mentioned in the Examples, the average particle size can be measured with a Brookhaven BI-90 analyzer, commercially available from Brookhaven Instrument Company, Holtsville, N.Y., USA.

In accordance with another preferred embodiment of the present invention, the amount of hydrophobic thermoplastic polymer particles contained in the image-recording layer is preferably more than about 70 wt. % and less than about 85 wt. %, preferably between about 75 wt. % and about 84 wt. %, more preferably between about 77 wt. % and about 83 wt. %.

The hydrophobic thermoplastic polymer particle includes a hydrophobic polymer. Specific examples of suitable hydrophobic polymers are, e.g., polyethylene, poly(vinyl chloride), poly(methyl(meth)acrylate), poly(ethyl(meth)acrylate), poly(vinylidene chloride), poly(meth)acrylonitrile, poly(vinyl carbazole), polystyrene, or copolymers thereof. Polystyrene and poly(meth)acrylonitrile or their derivatives are highly preferred embodiments. According to such preferred embodiments, the polymer includes at least about 50 wt. % of polystyrene, and more preferably at least about 60 wt. % of polystyrene. In order to obtain sufficient resistivity towards organic chemicals, such as the hydrocarbons used in plate cleaners, the polymer preferably includes at least about 5 wt. %, more preferably at least about 30 wt. % of nitrogen containing monomeric units or of units which correspond to monomers that are characterized by a solubility parameter larger than 20, such as (meth)acrylonitrile. Suitable examples of such nitrogen containing monomeric units are disclosed in EP-A 1 219 416. According to the most preferred embodiment, the polymer is a copolymer consisting essentially of styrene and acrylonitrile units in a weight ratio between 1:1 and 5:1 (styrene:acrylonitrile), e.g., in a 2:1 ratio.

The weight average molecular weight of the thermoplastic polymer particles may range from 5,000 g/mol to 1,000,000 g/mol.

The hydrophobic thermoplastic polymer particles are present as a dispersion in an aqueous coating liquid of the image-recording layer and may be prepared by the methods disclosed in U.S. Pat. No. 3,476,937. Another method that is especially suitable for preparing an aqueous dispersion of the thermoplastic polymer particles includes dissolving the hydrophobic thermoplastic polymer in an organic water immiscible solvent, dispersing the thus obtained solution in water or in an aqueous medium and removing the organic solvent by evaporation.

The image-recording layer further includes a hydrophilic binder. Specific examples of hydrophilic binders are homopolymers and copolymers of vinyl alcohol, acrylamide, methylol acrylamide, methylol methacrylamide, acrylic acid, methacrylic acid, hydroxyethyl acrylate, hydroxyethyl methacrylate, or maleic anhydride/vinylmethylether copolymers. The hydrophilicity of the (co)polymer or (co)polymer mixture used is preferably the same as or higher than the hydrophilicity of polyvinyl acetate hydrolyzed to at least an extent of 60 percent by weight, preferably 80 percent by weight.

In accordance with another preferred embodiment of the present invention, the image-recording layer preferably has a coating weight between about 0.45 g/m² and about 0.83 g/m², more preferably between about 0.50 g/m² and about 0.80 g/m², most preferably about 0.55 g/m² and about 0.75 g/m².

The coating may include, besides the image recording layer, one or more additional layer(s). Such an additional layer can be, e.g., an adhesion-improving layer between the image-recording layer and the support, or a light-absorbing layer including one or more of the above compounds that are capable of converting infrared light into heat, or a covering layer which is removed during processing with a gum solution.

The image-recording layer or an additional layer preferably further contains a pigment having a hydrophilic surface and provides a visible image after image-wise exposing and developing with a gum solution. The hydrophilicity of the surface may be formed by the presence of hydrophilic groups, such as anionic or non-ionic groups, on the surface of the pigment particle. A hydrophilic surface may be formed by surface treatment, coating or adsorption of compounds such as hydrophilic polymers, reactive materials (e.g., silane coupling agent, an epoxy compound, polyisocyanate, or the like), surfactants (e.g., anionic or non-ionic surfactants) or water soluble salts (e.g., salts of phosphoric acid). Typical hydrophilic polymers are polymers or copolymers having anionic groups such as carboxylic acid, sulphonic acid, phosphonic acid, phosphoric acid, or salts thereof, or having a polyalkylene oxide group such as polyethyleneoxide. Specific examples of colorants are defined in the non-published EP-A 03 103 827. In accordance with preferred embodiments of the present invention, carbon dispersions in water such as CAB O JET 200, commercially available from CABOT, are preferred, and phthalocyanine pigment dispersions in water such as CAB O JET 250, commercially available from CABOT, are most preferred.

The image-recording layer or an additional layer may also include other ingredients such as additional binders, surfactants, development inhibitors or accelerators, and especially an IR-absorbing agent. An IR-absorbing agent is a compound capable of converting infrared light into heat. Particularly useful light-to-heat converting compounds or IR-absorbing agents are, for example, infrared dyes, carbon black, metal carbides, borides, nitrides, carbonitrides, bronze-structured oxides, and conductive polymer dispersions such as polypyrrole, polyaniline, or polythiophene dispersions.

In accordance with a preferred embodiment of the present invention, the coating preferably includes an IR-absorbing agent, more preferably the image recording layer includes an IR-absorbing agent, and most preferably the image recording layer includes an IR-absorbing agent in an amount of at least 6% by weight relative to the image recording layer.

The printing plate precursors used in the various preferred embodiments of the present invention are exposed to heat or to infrared light, e.g., by an infrared laser or LEDs. Preferably, a laser emitting near infrared light having a wavelength in the range from about 700 nm to about 1500 nm is used, e.g., a semiconductor laser diode, a Nd:YAG or a Nd:YLF laser. The required laser power depends on the sensitivity of the image-recording layer, the pixel dwell time of the laser beam, which is determined by the spot diameter (typical value of modern plate-setters at 1/e² of maximum intensity: 10 μm-25 μm), the scan speed and the resolution of the exposure apparatus (i.e., the number of addressable pixels per unit of linear distance, often expressed in dots per inch or dpi; typical value: 1000-4000 dpi). Two types of laser-exposure apparatuses are commonly used: internal (ITD) and external drum (XTD) plate-setters. ITD plate-setters for thermal plates are typically characterized by a very high scan speed up to 500 m/sec and may require a laser power of several Watts. XTD plate-setters for thermal plates having a typical laser power from about 200 mW to about 1 W operate at a lower scan speed, e.g., from 0.1 m/sec to 10 m/sec.

Due to the heat generated during the exposure step, the hydrophobic thermoplastic polymer particles fuse or coagulate so as to form a hydrophobic phase which corresponds to the printing areas of the printing plate. Coagulation may result from heat-induced coalescence, softening or melting of the thermoplastic polymer particles. There is no specific upper limit to the coagulation temperature of the thermoplastic hydrophobic polymer particles, however, the temperature should be sufficiently below the decomposition temperature of the polymer particles. Preferably the coagulation temperature is at least 10° C. below the temperature at which the decomposition of the polymer particles occurs. The coagulation temperature is preferably higher than 50° C., more preferably above 100° C.

In the development step, the non-exposed areas of the image-recording layer are removed by supplying a gum or baking gum solution without essentially removing the exposed areas, i.e., without affecting the exposed areas to an extent that renders the ink-acceptance of the exposed areas unacceptable. The development by supplying a gum or baking gum may be combined with mechanical rubbing, e.g., by a rotating brush. The gum or baking gum solution can be applied to the plate, e.g., by rubbing in with an impregnated pad, by dipping, (spin-)coating, spraying, or pouring-on, either by hand or in an automatic processing apparatus. After applying the baking gum solution, the plate can be dried before baking or is dried during the baking process itself. The baking process can proceed at a temperature above the coagulation temperature of the thermoplastic polymer particles, e.g., between 100° C. and 230° C. for a period of 5 to 40 minutes. For example, the exposed and developed plates can be baked at a temperature of about 230° C. for about 5 minutes, at a temperature of about 150° C. for about 10 minutes, or at a temperature of about 120° C. for about 30 minutes. Baking can be done in conventional hot air ovens or by irradiation with lamps emitting in the infrared or ultraviolet spectrum.

A gum solution is typically an aqueous liquid which includes one or more surface protective compounds that are capable of protecting the lithographic image of a printing plate against contamination, e.g., by oxidation, fingerprints, fats, oils or dust, or damaging, e.g., by scratches during handling of the plate. Suitable examples of such compounds are film-forming hydrophilic polymers or surfactants. The layer that remains on the plate after treatment with the gum solution preferably includes between about 0.1 g/m² and about 20 g/m² of the surface protective compound.

A gum solution is normally supplied as a concentrated solution which is diluted by the end user with water before use. In the present description, all concentrations of compounds present in the gum solution are expressed as percentage by weight (wt. % or % w/w) relative to the non-diluted gum solution, unless otherwise indicated.

Preferred polymers for use as protective compound in the gum solution are gum arabic, pullulan, cellulose derivatives such as carboxymethylcellulose, carboxyethylcellulose or methylcellulose, (cyclo)dextrin, poly(vinyl alcohol), poly(vinyl pyrrolidone), polysaccharide, homo- and copolymers of acrylic acid, methacrylic acid or acrylamide, a copolymer of vinyl methyl ether and maleic anhydride, a copolymer of vinyl acetate and maleic anhydride, or a copolymer of styrene and maleic anhydride. Highly preferred polymers are homo- or copolymers of monomers containing carboxylic, sulfonic or phosphonic groups or the salts thereof, e.g., (meth)acrylic acid, vinyl acetate, styrene sulfonic acid, vinyl sulfonic acid, vinyl phosphonic acid, or acrylamidopropane sulfonic acid.

Examples of surfactants for use as surface protective agent include anionic or nonionic surfactants. The gum solution may also include one or more of the above hydrophilic polymers as a surface protective agent and, in addition, one or more surfactants to improve the surface properties of the coated layer. The surface tension of the gum solution is preferably from about 40 mN/m to about 50 mN/m.

The gum solution preferably includes an anionic surfactant, more preferably an anionic surfactant wherein the anionic group is a sulphonic acid group.

Examples of the anionic surfactant include aliphates, abietates, hydroxyalkanesulfonates, alkanesulfonates, dialkylsulfosuccinates, straight-chain alkylbenzenesulfonates, branched alkylbenzenesulfonates, alkylnaphthalenesulfonates, alkylphenoxypolyoxyethylenepropylsulfonates, salts of polyoxyethylene alkylsulfophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphatic alkylesters, salts of alkylsulfuric esters, sulfuric esters of polyoxyethylenealkylethers, salts of sulfuric esters of aliphatic monoglycerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrenemaleic anhydride copolymers, partially saponified compounds of olefin-maleic anhydride copolymers, and naphthalenesulfonateformalin condensates. Particularly preferred among these anionic surfactants are dialkylsulfosuccinates, salts of alkylsulfuric esters and alkylnaphthalenesulfonates.

Specific examples of suitable anionic surfactants include sodium dodecylphenoxybenzene disulfonate, the sodium salt of alkylated naphthalenesulfonate, disodium methylene-dinaphtalene-disulfonate, sodium dodecyl-benzenesulfonate, sulfonated alkyl-diphenyloxide, ammonium or potassium perfluoroalkylsulfonate, and sodium dioctyl-sulfosuccinate.

Suitable examples of the nonionic surfactants include polyoxyethylene alkyl ethers, polyoxyethylene alkyl phenyl ethers, polyoxyethylene polystyryl phenyl ethers, polyoxyethylene polyoxypropylene alkyl ethers, polyoxyethylene polyoxypropylene block polymers, partial esters of glycerinaliphatic acids, partial esters of sorbitanaliphatic acid, partial esters of pentaerythritolaliphatic acid, propyleneglycolmonoaliphatic esters, partial esters of sucrosealiphatic acids, partial esters of polyoxyethylenesorbitanaliphatic acid, partial esters of polyoxyethylenesorbitolaliphatic acids, polyethyleneglycolaliphatic esters, partial esters of poly-glycerinaliphatic acids, polyoxyethylenated castor oils, partial esters of polyoxyethyleneglycerinaliphatic acids, aliphatic diethanolamides, N,N-bis-2-hydroxyalkylamines, polyoxyethylene alkylamines, triethanolaminealiphatic esters, and trialkylamine oxides. Particularly preferred among these nonionic surfactants are polyoxyethylene alkylphenyl ethers and poloxyethylenepolyoxypropylene block polymers. Further, fluorinic and siliconic anionic and nonionic surfactants may be similarly used.

Two or more of the above surfactants may be used in combination. For example, a combination of two or more different anionic surfactants or a combination of an anionic surfactant and a nonionic surfactant may be preferred. The amount of such a surfactant is not specifically limited but is preferably from about 0.01 wt. % to about 20 wt. %.

The gum solution preferably has a pH from about 3 to about 8, more preferably between about 5 and about 8, most preferably between about 5 and about 7. The pH of the gum solution is usually adjusted with a mineral acid, an organic acid, or an inorganic salt in an amount of from about 0.01 wt. % to about 2 wt. %. Examples of the mineral acids include nitric acid, sulfuric acid, phosphoric acid, and metaphosphoric acid. Especially organic acids are used as pH control agents and as desensitizing agents. Examples of the organic acids include carboxylic acids, sulfonic acids, phosphonic acids or salts thereof, e.g., succinates, phosphates, phosphonates, sulfates, and sulfonates. Specific examples of the organic acid include citric acid, acetic acid, oxalic acid, malonic acid, p-toluenesulfonic acid, tartaric acid, malic acid, lactic acid, levulinic acid, phytic acid, and organic phosphonic acid.

The gum solution may also include an inorganic salt, preferably a mono or dibasic phosphate salt, more preferably an alkali-metal dihydrogen phosphate such as KH₂PO₄ or NaH₂PO₄.

Examples of the inorganic salt include magnesium nitrate, monobasic sodium phosphate, dibasic sodium phosphate, nickel sulfate, sodium hexametaphosphate, and sodium tripolyphosphate. Other inorganic salts can be used as corrosion inhibiting agents, e.g., magnesium sulfate or zinc nitrate. The mineral acid, organic acid, or inorganic salt may be used singly or in combination with one or more thereof.

The gum solution may also include a mixture of an anionic surfactant and an inorganic salt. In this mixture the anionic surfactant is preferably an anionic surfactant with a sulphonic acid group, more preferably an alkali-metal salt of a mono- or di-alkyl substituted diphenylether-sulphonic acid, and the inorganic salt is preferably a mono or dibasic phosphate salt, more preferably an alkali-metal dihydrogen phosphate, most preferably KH₂PO₄ or NaH₂PO₄.

Besides the foregoing components, a wetting agent such as ethylene glycol, propylene glycol, triethylene glycol, butylene glycol, hexylene glycol, diethylene glycol, dipropylene glycol, glycerin, trimethylol propane, and diglycerin may also be present in the gum solution. The wetting agent may be used singly or in combination with one or more thereof. In general, the foregoing wetting agent is preferably used in an amount of from about 1 wt. % to about 25 wt. %.

Further, a chelate compound may be present in the gum solution. Calcium ion and other impurities contained in the diluting water can have adverse effects on printing and thus cause the contamination of printed matter. This problem can be eliminated by adding a chelate compound to the diluting water. Preferred examples of such a chelate compound include organic phosphonic acids or phosphonoalkanetricarboxylic acids. Specific examples are potassium or sodium salts of ethylenediaminetetraacetic acid, diethylenetriaminepentaacetic acid, triethylenetetraminehexaacetic acid, hydroxyethylethylenediaminetriacetic acid, nitrilotriacetic acid, 1-hydroxyethane-1,1-diphosphonic acid and aminotri(methylenephosphonic acid). Besides these sodium or potassium salts of these chelating agents, organic amine salts are useful. The preferred amount of such a chelating agent to be added is from about 0.001 wt. % to about 1.0 wt. % relative to the gum solution in diluted form.

Further, an antiseptic and an anti-foaming agent may be present in the gum solution. Examples of such an antiseptic include phenol, derivatives thereof, formalin, imidazole derivatives, sodium dehydroacetate, 4-isothiazoline-3-one derivatives, benzoisothiazoline-3-one, benztriazole derivatives, amidineguanidine derivatives, quaternary ammonium salts, pyridine derivatives, quinoline derivatives, guanidine derivatives, diazine, triazole derivatives, oxazole, and oxazine derivatives. The preferred amount of such an antiseptic to be added is such that it can exert a stable effect on bacteria, fungi, yeast or the like. Though depending on the kind of bacteria, fungi and yeast, it is preferably from about 0.01 wt. % to about 4 wt. % relative to the gum solution in diluted form. Further, preferably, two or more antiseptics may be used in combination to exert an aseptic effect on various fungi and bacteria. The anti-foaming agent is preferably silicone anti-foaming agents. Among these anti-foaming agents, either an emulsion dispersion type or solubilized type anti-foaming agent may be used. The proper amount of such an anti-foaming agent to be added is from about 0.001 wt. % to about 1.0 wt. % relative to the gum solution in diluted form.

Besides the foregoing components, an ink receptivity agent may be present in the gum solution if desired. Examples of such an ink receptivity agent include turpentine oil, xylene, toluene, low heptane, solvent naphtha, kerosine, mineral spirit, hydrocarbons such as petroleum fraction having a boiling point of about 120° C. to about 250° C., diester phthalates (e.g., dibutyl phthalate, diheptyl phthalate, di-n-octyl phthalate, di(2-ethylhexyl)phthalate, dinonyl phthalate, didecyl phthalate, dilauryl phthalate, butylbenzyl phthalate), aliphatic dibasic esters (e.g., dioctyl adipate, butylglycol adipate, dioctyl azelate, dibutyl sebacate, di(2-ethylhexyl)sebacate dioctyl sebacate), epoxidated triglycerides (e.g., epoxy soyabean oil), ester phosphates (e.g., tricresyl phosphate, trioctyl phosphate, trischloroethyl phosphate) and plasticizers having a solidification point of 15° C. or less and a boiling point of 300° C. or more at one atmospheric pressure such as esters of benzoates (e.g., benzyl benzoate). Examples of other solvents which can be used in combination with these solvents include ketones (e.g., cyclohexanone), halogenated hydrocarbons (e.g., ethylene dichloride), ethylene glycol ethers (e.g., ethylene glycol monomethyl ether, ethylene glycol monophenyl ether, ethylene glycol monobutyl ether), aliphatic acids (e.g., caproic acid, enathic acid, caprylic acid, pelargonic acid, capric acid, undecylic acid, lauric acid, tridecylic acid, myristic acid, pentadecylic acid, palmitic acid, heptadecylic acid, stearic acid, nonadecanic acid, arachic acid, behenic acid, lignoceric acid, cerotic acid, heptacosanoic acid, montanic acid, melissic acid, lacceric acid, isovaleric acid) and unsaturated aliphatic acids (e.g., acrylic acid, crotonic acid, isocrotonic acid, undecyclic acid, oleic acid, elaidic acid, cetoleic acid, erucic acid, butecidic acid, sorbic acid, linoleic acid, linolenic acid, arachidonic acid, propiolic acid, stearolic acid, clupanodonic acid, tariric acid, licanic acid). Preferably, it is an aliphatic acid which is liquid at a temperature of 50° C., more preferably has from 5 to 25 carbon atoms, most preferably has from 8 to 21 carbon atoms. The ink receptivity agent may be used singly or in combination with one or more thereof. The ink receptivity agent is preferably used in an amount of from about 0.01 wt. % to about 10 wt. %, more preferably from about 0.05 wt. % to about 5 wt. %. The foregoing ink receptivity agent may be present as an oil-in-water emulsion or may be solubilized with the aid of a solubilizing agent.

The viscosity of the gum solution can be adjusted to a value of, e.g., between about 1.7 and about 5 cP, by adding viscosity increasing compounds, such as poly(ethylene oxide), e.g., having a molecular weight between 10⁵ and 10⁷. Such compounds can be present in a concentration of about 0.01 g/l to about 10 g/l.

A baking gum has a similar composition as described above, with the additional preference towards compounds that do not evaporate at the usual bake temperatures. Specific examples of suitable baking gum solutions are described in, e.g., EP-A 222 297, EP-A 1 025 992, DE-A 2 626 473, and U.S. Pat. No. 4,786,581.

### Examples

### Preparation of the Lithographic Substrate

A 0.30 mm thick aluminum foil was degreased by immersing the foil in an aqueous solution containing 40 g/l of sodium hydroxide at 60° C. for 8 seconds and rinsed with demineralized water for 2 seconds. The foil was then electrochemically grained during 15 seconds using an alternating current in an aqueous solution containing 12 g/l of hydrochloric acid and 38 g/l of aluminum sulfate (18-hydrate) at a temperature of 33° C. and a current density of 130 A/dm². After rinsing with demineralized water for 2 seconds, the aluminum foil was then desmutted by etching with an aqueous solution containing 155 g/l of sulfuric acid at 70° C. for 4 seconds and rinsed with demineralized water at 25° C. for 2 seconds. The foil was subsequently subjected to anodic oxidation during 13 seconds in an aqueous solution containing 155 g/l of sulfuric acid at a temperature of 45° C. and a current density of 22 A/dm², then washed with demineralized water for 2 seconds and post-treated for 10 seconds with a solution containing 4 g/l of polyvinylphosphonic acid at 40° C., rinsed with demineralized water at 20° C. during 2 seconds and dried.

The support thus obtained has a surface roughness Ra of 0.21 μm and an anodic weight of 4 g/m² of Al₂O₃.

### Preparation of the Printing Plate Precursors 1-2.

Printing plate precursors 1 and 2 were produced by applying a coating solution onto the above described lithographic substrate. The composition of the coating is defined in Table 1. The average particle sizes of the styrene/acrylonitrile copolymers were measured with a Brookhaven BI-90 analyzer, commercially available from Brookhaven Instrument Company, Holtsville, N.Y., USA, and are indicated in Table 2. The coating was applied from an aqueous coating solution and a dry coating weight of 0.8 g/m² was obtained.

TABLE 1
composition of the dry coating (% wt)

| INGREDIENTS | % wt |
|---|---|
| Polymer particle (1) | 77 |
| IR-2 (2) | 10 |
| Polyacrylic acid binder (3) | 10 |
| Cab O Jet 200 (4) | 3 |

(1) Polymer particle is copolymer of styrene/acrylonitrile, weight ratio
60/40, stabilized with an anionic wetting agent; average particle size as
defined in Table 2;
(2) Infrared absorbing dye IR-2 has the following structure:

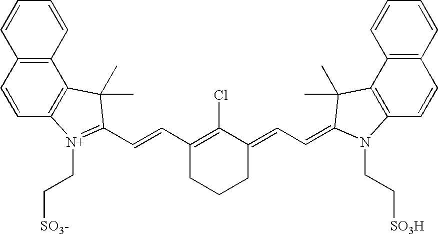

(3) Glascol D15 from ALLIED COLLOIDS, Mw = 2.7 × 10⁷ g/mol;
(4) Carbon dispersion in water from CABOT.

### Imaging and Processing of the Printing Plate Precursors 1-2.

The plate precursors 1 and 2 were exposed with a Creo Trendsetter 2344T (40W) (plate-setter, trademark from CREO, Burnaby, Canada), operating at 150 rpm and varying energy densities up to 330 mJ/cm².

After imaging, the plate precursors were developed in a gumming unit, using Agfa RC520 (trademark of AGFA) as a gumming solution. The RC520 solution is an aqueous solution of the surfactant DOWFAX 3B2, commercially available from DOW CHEMICAL, in a concentration of 39.3 g/l, citric acid.laq in a concentration of 9.8 g/l, and trisodium citrate.2aq in a concentration of 32.6 g/l, and the RC520 solution has a pH-value of about 5.

### Print Results.

The plates were mounted on a GTO46 printing press (available from Heidelberger Druckmaschinen AG), and a print job was started using K+E Novavit 800 Skinnex ink (trademark of BASF Drucksysteme GmbH) and 3% FS101 (trademark of AGFA) in 10% isopropanol as fountain liquid.

The lithographic properties of the plates were determined by visual inspection of the clean-out in the non-exposed areas and the appearance of toning in the non-exposed areas on the press and by the run-length resistance (Table 2). A good run length resistance (+) means that after 100,000 prints the 2% highlight of a 200 lpi screen was still rendered on the print. An insufficient run length resistance (−) means that after 1,000 prints breakdown of the highlight of a 200 lpi screen occurred.

TABLE 2
results of run-length and sensitivity.

| | | Average | | | |
|---|---|---|---|---|---|
| | | particle | Sensitivity | Energy | Run |
| Example | Plate | size | (*) | exposed | length |
| number | precursor | nm | (mJ/cm²) | (mJ/cm²) | (**) |
| Invention | Precursor | 51 | 215 | 215 | + |
| Example 1 | 1 | | | 260 | + |
| | | | | 330 | + |
| Comparative | Precursor | 65 | 330 | 215 | − |
| Example 1 | 2 | | | 260 | − |
| | | | | 330 | + |

(*) energy required for a clear reproduction of a 2% dot
of a 200 lpi screen on the printed copies;
(**) see above.

The Invention Example 1 and the Comparative Example 1 show both an excellent clean-out and no toning. The results in Table 2 demonstrate that the Precursor 1, including a latex with an average particle size of 51 nm, has an improved sensitivity and a good run length. In the Comparative Example 1, the Precursor 2, including a latex with an average particle size of 65 nm, exhibits only a high run length with high exposure energy dose and has a reduced sensitivity.

### Preparation of the Printing Plate Precursors 3-6.

Printing plate precursors 3 to 6 were produced by applying a coating solution onto the above described lithographic substrate. The composition of the coating is defined in Table 3. The average particle sizes of the styrene/acrylonitrile copolymers were measured with a Brookhaven BI-90 analyzer, commercially available from Brookhaven Instrument Company, Holtsville, N.Y., USA, and are indicated in Table 4. The coating was applied from an aqueous coating solution and a dry coating weight of 0.6 g/cm² was obtained.

TABLE 3
composition of the dry coating (% wt)

| INGREDIENTS | % wt |
|---|---|
| Polymer particle (1) | 77 |
| IR-2 (2) | 10 |
| Polyacrylic acid binder (3) | 10 |
| Cab O Jet 200 (4) | 3 |

(1) Polymer particle is copolymer of styrene/acrylonitrile, weight ratio 60/40, stabilized with an anionic wetting agent; average particle size as defined in Table 4;
(2) IR-2 as defined in Table 1;
(3) Glascol D15 from ALLIED COLLOIDS;
(4) Carbon dispersion in water from CABOT.

### Imaging and Processing of the Printing Plate Precursors 3-6.

The plate precursors 3-6 were exposed with a Creo Trendsetter 2344T (40W) (plate-setter, trademark of CREO, Burnaby, Canada), operating at 150 rpm and varying energy densities up to 330 mJ/cm².

After imaging, the plate precursors were developed in a gumming unit, using Agfa RC520 (trademark from AGFA) as gumming solution.

### Print Results.

The plates were mounted on a GTO46 printing press (available from Heidelberger Druckmaschinen AG), and a print job was started using K+E Novavit 800 Skinnex ink (trademark of BASF Drucksysteme GmbH) and 3% FS101 (trademark of AGFA) in 10% isopropanol as fountain liquid.

The sensitivity, clean-out and toning were determined for these precursors as described in Invention Example 1 and are summarized in Table 4.

TABLE 4
results of sensitivity and appearance of toning
in the non-image areas of the plate.

| | | Average | | | |
|---|---|---|---|---|---|
| | | particle | Sensitivity | Clean-out | Toning |
| Example | Plate | size | (*) | Behavior | Behavior |
| number | precursor | nm | (mJ/cm²) | (**) | (***) |
| Comparative | Precursor | 36 | — | − | − |
| Example 2 | 3 | | | | |
| Invention | Precursor | 45 | 110 | + | + |
| Example 2 | 4 | | | | |
| Invention | Precursor | 50 | 150 | + | + |
| Example 3 | 5 | | | | |
| Invention | Precursor | 61 | 170 | + | + |
| Example 4 | 6 | | | | |

(*) energy required for a clear reproduction of a 2% dot of a 200 lpi screen on the printed copies;
(**) + indicates an excellent clean-out; − indicated an insufficient clean-out;
(***) + indicates no toning; − indicates toning.

The results in Table 4 demonstrate that the precursors, including a latex with an average particle size ≧45 nm, exhibit an excellent clean-out and no toning and a high sensitivity. In the Comparative Example 2, the Precursor 3, including a latex with a particle size of 36 nm, shows an insufficient clean-out and toning.

### Preparation of the Printing Plate Precursors 7-12.

The printing plate precursors 7 to 12 were produced by applying a coating onto the above described lithographic substrate. The composition of the coating is defined in Table 5. The coating was applied from an aqueous coating solution and a dry coating weight of 0.6 g/cm² was obtained.

TABLE 5
Composition of the dry coating (% wt)

| | Polymer | IR-2 | Binder | Cab O Jet |
|---|---|---|---|---|
| Plate precursor | particle (1) | (2) | (3) | 250 (4) |
| Precursor 7 | 65% | 6% | 26% | 3% |
| Precursor 8 | 75% | 6% | 16% | 3% |
| Precursor 9 | 79% | 8% | 6% | 7% |
| Precursor 10 | 81% | 8% | 6% | 5% |
| Precursor 11 | 83% | 8% | 6% | 3% |
| Precursor 12 | 85% | 6% | 6% | 3% |

(1) Polymer particle is copolymer of styrene/acrylonitrile, weight ratio 60/40, stabilized with an anionic wetting agent; average particle size 51 nm, measured with a Brookhaven BI-90 analyzer, commercially available from Brookhaven Instrument Company, Holtsville, NY, USA;
(2) IR-2 as defined in Table 1;
(3) Glascol D15 from ALLIED COLLOIDS
(4) Cu-Phtalocyanine-dispersion in water from CABOT.

### Imaging and Processing of the Printing Plate Precursors 7-12.

The plate precursors 7-12 were exposed with a Creo Trendsetter 2344T (40W) (plate-setter, trademark from CREO, Burnaby, Canada), operating at 150 rpm and varying energy densities up to 330 mJ/cm².

After imaging, the plate precursors were developed in a gumming unit, using Agfa RC520 (trademark from AGFA) as gumming solution.

### Print Results.

The plates were mounted on a GTO46 printing press (available from Heidelberger Druckmaschinen AG) and a print job was started using K+E Novavit 800 Skinnex ink (trademark of BASF Drucksysteme GmbH) and 3% FS101 (trademark from Agfa) with 10% isopropanol as fountain liquid.

The sensitivity, clean-out and toning were determined for these precursors as described in Invention Example 1 and are summarized in Table 6.

TABLE 6
results of sensitivity and appearance of toning
in the non-image areas of the plate.

| | | Sensitivity | Clean-out | Toning |
|---|---|---|---|---|
| Example | Plate | (*) | Behavior | Behavior |
| number | precursor | (mJ/cm²) | (**) | (***) |
| Comparative | Precursor 7 | 330 | + | + |
| Example 3 | | | | |
| Invention | Precursor 8 | 190 | + | + |
| Example 5 | | | | |
| Invention | Precursor 9 | 190 | + | + |
| Example 6 | | | | |
| Invention | Precursor 10 | 190 | + | + |
| Example 7 | | | | |
| Invention | Precursor 11 | 190 | + | + |
| Example 8 | | | | |
| Comparative | Precursor 12 | — | − | − |
| Example 4 | | | | |

(*) energy required for a clear reproduction of a 2% dot of a 200 lpi screen on the printed copies;
(**) + indicates an excellent clean-out; − indicated an insufficient clean-out;
(***) + indicates no toning; − indicates toning.

The results in Table 6 demonstrate that the precursors, including a latex of 51 nm in an amount of <85% wt, exhibit an excellent clean-out and no toning, but a high sensitivity is only obtained for an amount of the latex >65% wt, namely for the Precursor 7, including 65% wt of the latex, a sensitivity of 330 mJ/m² is obtained.

### Preparation of the Printing Plate Precursors 13-16.

The printing plate precursors 13 to 16 were produced in the same way as the precursors 7 to 12 with the exception that the Cab 0 Jet 250 is replaced by Cap 0 Jet 200 in the same amounts. The composition of the coating for the precursors 13 to 16 is defined in Table 7. The coating was applied from an aqueous coating solution onto the above described lithographic substrate, and a dry coating weight of 0.6 g/cm² was obtained.

TABLE 7
composition of the dry coating (% wt)

| | Polymer | IR-2 | Binder | Cab O Jet |
|---|---|---|---|---|
| Plate precursor | particle (1) | (2) | (3) | 200 (4) |
| Precursor 13 | 65% | 6% | 26% | 3% |
| Precursor 14 | 75% | 6% | 16% | 3% |
| Precursor 15 | 83% | 8% | 6% | 3% |
| Precursor 16 | 85% | 6% | 6% | 3% |

(1) Polymer particle is copolymer of styrene/acrylonitrile, weight ratio 60/40, stabilized with an anionic wetting agent; average particle size of 51 nm, measured with a Brookhaven BI-90 analyzer, commercially available from Brookhaven Instrument Company, Holtsville, NY, USA;
(2) IR-2 as defined in Table 1;
(3) Glascol D15 from ALLIED COLLOIDS;
(4) Carbon dispersion in water from CABOT.

### Imaging and Processing of the Printing Plate Precursors 13-16.

The plate precursors 13-16 were exposed and processed in an identical way as defined above for the precursors 7-12.

### Print Results.

The plates were mounted on a GTO46 printing press (available from Heidelberger Druckmaschinen AG) and a print job was started using K+E Novavit 800 Skinnex ink (trademark of BASF Drucksysteme GmbH) and 3% FS101 (trademark of AGFA) with 10% isopropanol as fountain liquid.

The sensitivity, clean-out and toning were determined for these precursors as described in Invention Example 1 and are summarized in Table 8.

TABLE 8
results of sensitivity and appearance of toning
in the non-image areas of the plate.

| | | Sensitivity | Clean-out | Toning |
|---|---|---|---|---|
| Example | Plate | (*) | Behavior | Behavior |
| number | precursor | (mJ/cm²) | (**) | (***) |
| Comparative | Precursor | 330 | + | + |
| Example 5 | 13 | | | |
| Invention | Precursor | 210 | + | + |
| Example 9 | 14 | | | |
| Invention | Precursor | 190 | + | + |
| Example 10 | 15 | | | |
| Comparative | Precursor | — | − | + |
| Example 6 | 16 | | | |

(*) energy required for a clear reproduction of a 2% dot of a 200 lpi screen on the printed copies;
(**) + indicates an excellent clean-out; − indicated an insufficient clean-out;
(***) + indicates no toning; − indicates toning.

The results in Table 8 demonstrate that the precursors, including a latex of 51 nm in an amount of <85% wt, exhibit an excellent clean-out and no toning, but a high sensitivity is only obtained for an amount of the latex >65% wt, namely for the Precursor 13, including 65% wt of the latex, a sensitivity of 330 mJ/m² is obtained.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-17. (canceled)

18: A method of making a lithographic printing plate comprising the steps of:
providing a lithographic printing plate precursor including:
a support having a hydrophilic surface or which is provided with a hydrophilic layer; and
a coating provided on the support and including an image recording layer including hydrophobic thermoplastic polymer particles and a hydrophilic binder, the coating further including a pigment present in the image recording layer or in an additional layer of the coating;
image-wise exposing the coating, thereby inducing coalescence of the thermoplastic polymer particles at the exposed areas of the image recording layer;
developing the precursor by applying a gum solution to the coating, thereby removing the non-exposed areas of the image recording layer from the support; and
optionally, baking the developed precursor; wherein
the hydrophobic thermoplastic polymer particles have an average particle size between about 40 nm and about 63 nm;
the amount of the hydrophobic thermoplastic polymer particles is more than about 70% and less than about 85% by weight, relative to the image recording layer; and
the pigment has a hydrophilic surface and provides a visible image after the image-wise exposing and developing with the gum solution.

19: A method according to claim 18, wherein the particles have an average particle size between about 45 nm and about 63 nm.

20: A method according to claim 18, wherein the particles have an average particle size between about 45 nm and about 59 nm.

21: A method according to claim 18, wherein the amount of the hydrophobic thermoplastic polymer particles ranges from about 75% to about 84% by weight, relative to the image recording layer.

22: A method according to claim 18, wherein the amount of the hydrophobic thermoplastic polymer particles ranges from about 77% to about 83% by weight, relative to the image recording layer.

23: A method according to claim 18, wherein the coating weight of the image recording layer ranges between about 0.45 g/m² and about 0.85 g/m².

24: A method according to claim 18, wherein the coating weight of the image recording layer ranges between about 0.50 g/m² and about 0.80 g/m².

25: A method according to claim 18, wherein the coating weight of the image recording layer ranges between about 0.55 g/m² and about 0.75 g/m².

26: A method according to claim 18, wherein the hydrophobic thermoplastic polymer particles include a copolymer of styrene and acrylonitrile or methacrylonitrile.

27: A method according to claim 18, wherein the coating further includes an IR-absorbing agent.

28: A method according to claim 27, wherein the IR-absorbing agent is present in the image recording layer in an amount of at least about 6% by weight relative to the image recording layer.

29: A method according to claim 18, wherein the pigment has hydrophilic groups on the surface.

30: A method according to claim 29, wherein the hydrophilic groups are anionic or non-ionic groups.

31: A method according to claim 18, wherein the gum solution contains a hydrophilic film-forming polymer and/or surfactant and wherein the pH of the gum solution ranges between 3 and 8.

32: A method according to claim 18, wherein the developing is carried out in a gumming unit which is provided with at least one roller for rubbing and/or brushing the coating during development.

33: A method according to claim 32, wherein the image-wise exposing step is carried out in a plate setter which is mechanically coupled to the gumming unit by a conveyor.

34: A method according to claim 32, wherein the optional baking step is carried out in a baking unit which is mechanically coupled to the gumming unit by a conveyor.

35: A method according to claim 33, wherein the optional baking step is carried out in a baking unit which is mechanically coupled to the gumming unit by a conveyor.
